(19) United States
(12) Patent Application Publication
(10) Pub. No.: US 2014/0153199 A1
(43) Pub. Date: Jun. 5, 2014

(54) MOUNTING APPARATUS FOR CONVERSION CARD

(71) Applicants: Hong Fu Jin Precision Industry (ShenZhen) Co., Ltd., (US); Hon Hai Precision Industry Co., Ltd., (US)

(72) Inventors: JUN-HUI WANG, Shenzhen (CN); XIAO-GANG YIN, Shenzhen (CN)

(73) Assignees: HON HAI PRECISION INDUSTRY CO., LTD., New Taipei (TW); Hong Fu Jin Precision Industry (ShenZhen) Co., Ltd, Shenzhen (CN)

(21) Appl. No.: 13/717,720

(22) Filed: Dec. 18, 2012

(30) Foreign Application Priority Data
Dec. 5, 2012 (CN) 201210515188.4

(51) Int. Cl. H05K 1/02

(52) U.S. Cl. CPC H05K 1/0213
USPC 361/748

(57) ABSTRACT

A mounting apparatus for fixing a conversion card to a motherboard of a chassis includes a main body and an assistant member. The assistant member includes a top board, and a side board to which the conversion card is fixed. The assistant member includes a handle mounted to the top board and adjacent to the conversion card. The handle is operated to move the mounting apparatus together with the conversion card away from the motherboard.

### BACKGROUND

1. Technical Field

The present disclosure relates to an apparatus for mounting one or more conversion cards.

2. Description of Related Art

Conversion cards are individually mounted to a bottom of a board that is fixed to a chassis. When disengaging a conversion card, the board needs to be disengaged from the chassis first, and then the board is moved up to disengage the conversion card from a corresponding connector on a motherboard of the chassis.

However, when a size of the board is large, or the conversion card is firmly engaged in the connector, it may be difficult to disengage the conversion card. Furthermore, when users try to forcibly disengage the conversion card from the connector, it may destroy the conversion card and pins of the connector.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting apparatus, together with a conversion card.

FIG. 2 is an assembled, isometric view of FIG. 1.

FIG. 3 is a cross-sectional view of FIG. 2, taken along the line III-III.

FIG. 4 is a partially assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

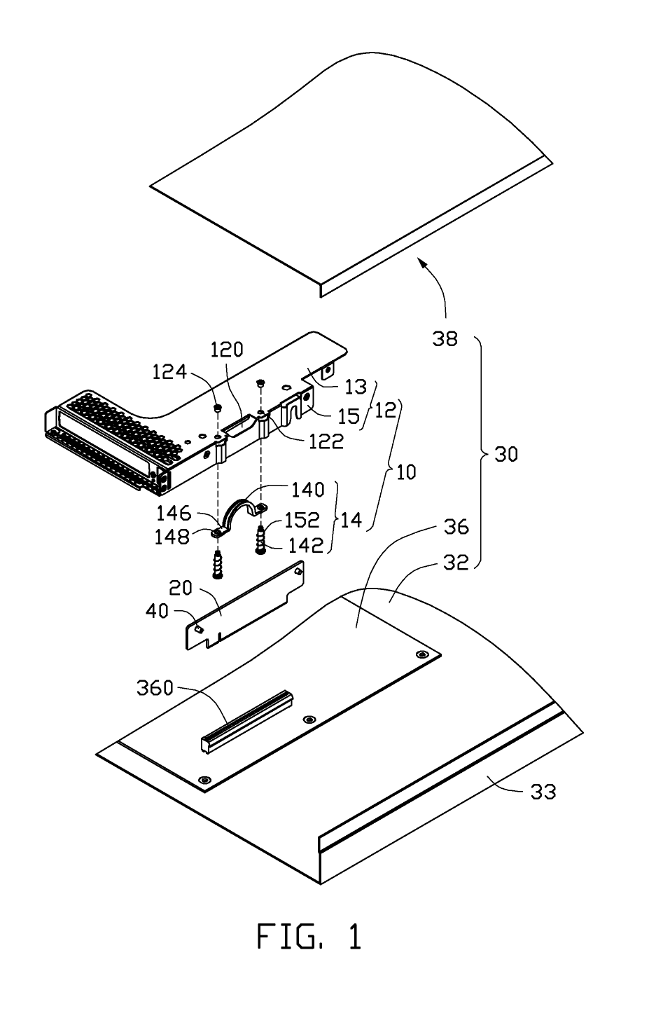

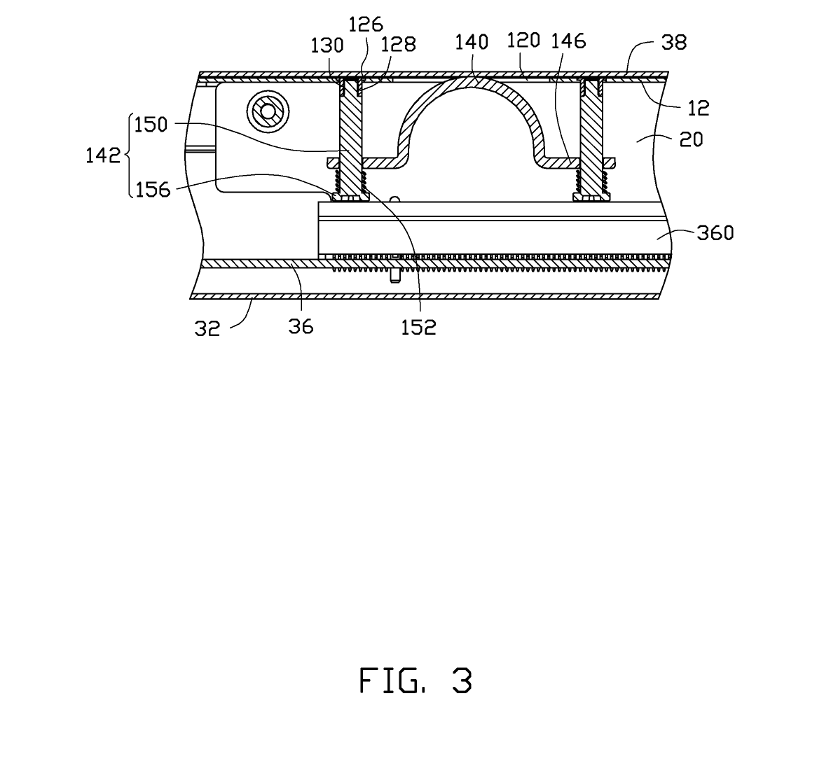

FIGS. 1 and 3 show an exemplary embodiment of a mounting apparatus 10 used for installing a conversion card 20 to a chassis 30.

The chassis 30 includes a bottom wall 32, sidewalls 33 connected to edges of the bottom wall 32, a motherboard 36 mounted on the bottom wall 32, and a cover 38. A connector 360 is mounted on the motherboard 36.

The mounting apparatus 10 includes a main body 12 and an assistant member 14.

The main body 12 includes a top board 13 and a side board 15 perpendicularly extending down from a side of the top board 13. An opening 120 and two through holes 122 at opposite ends of the opening 120 are defined in the top board 13, adjacent to the side board 15. In this embodiment, the opening 120 is defined in the joint of the top and side boards 13 and 15. A nut 124 is embedded in each through hole 122. Each nut 124 includes a pole 128 extending through the corresponding through hole 122 and axially defining a threaded hole 130 in a bottom end, and a head 126 connected to a top end of the pole 128 and abutted a top surface of the top board 13.

The assistant member 14 includes a semicircular handle 140, two springs 152, and two screws 142. Two fixing pieces 146 each defining a fixing hole 148 extend out from opposite ends of the handle 140. Each screw 142 includes a pole 156 and a head 150 connected to an end of the pole 156. A distal end of the pole 156 is threaded. The springs 152 are respectively fitted around the poles 150 between the distal end and the head 150.

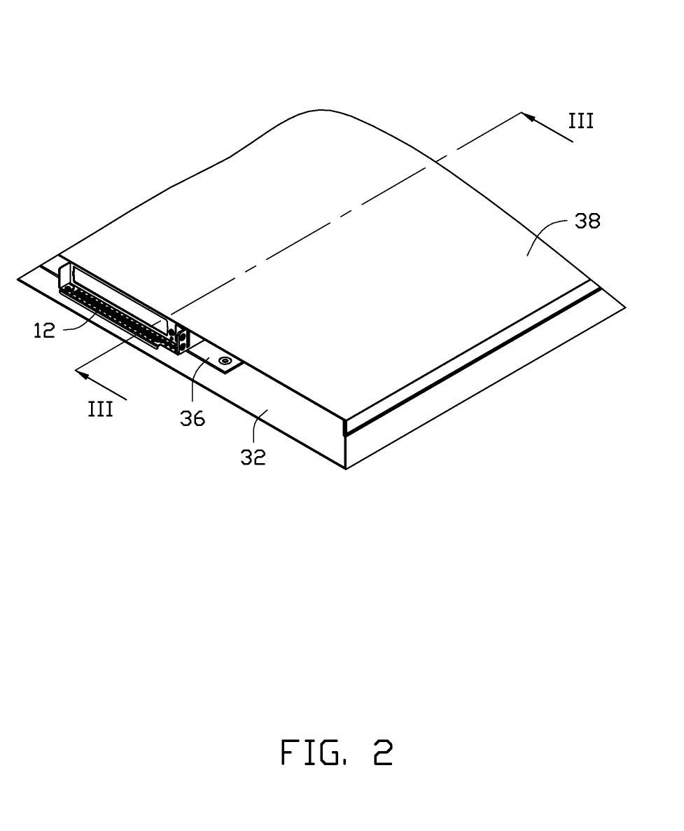

FIGS. 2 and 3 show that in assembly, the fixing pieces 146 are movably fitted about the poles 156 through the fixing holes 148 respectively. The distal ends of the pole 150 are respectively engaged in the corresponding threaded holes 130, thereby movably mounting the handle 14 to the main body 12 along the extending direction of the pole 150. Each spring 152 is resiliently sandwiched between the corresponding head 156 and the corresponding fixing piece 146. The handle 14 extends out of the top board 13 through the opening 120.

Two fasteners 40 extend through the conversion card 20 and then are engaged in the side board 15 to fix the conversion card 20 to an inner surface of the side board 15.

The conversion card 20 is inserted into the connector 360. A bottom of the main body 12 may be fixed to the chassis 30. After the cover 38 is covered on the sidewalls 33, the handle 140 is pushed down by the cover 38 and deforms the springs 152, until a top of the handle 140 is retracted into the opening 120.

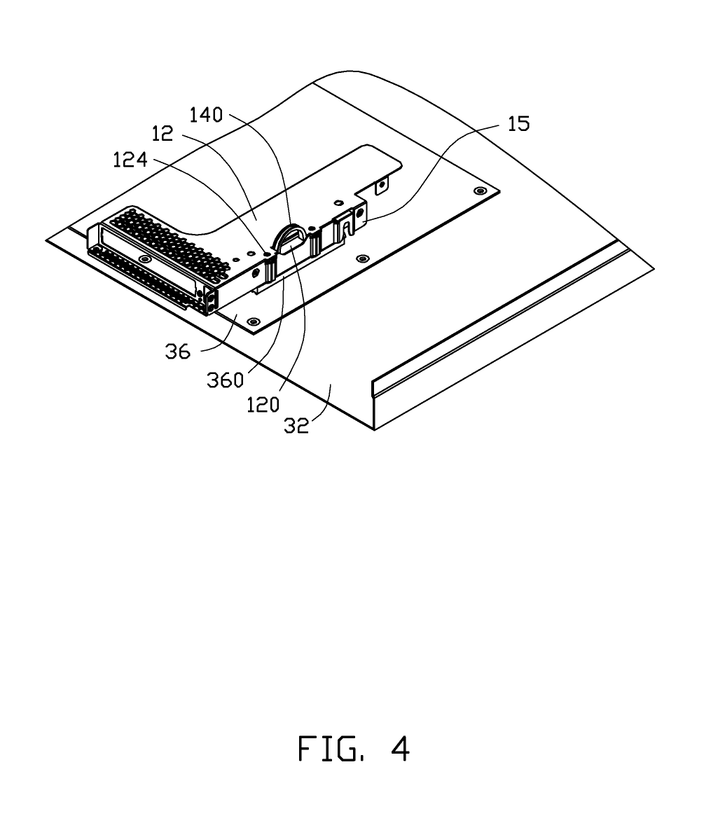

FIG. 4 shows that when disengaging the conversion card 20, the cover 38 is taken off, the springs 152 are restored and push the handle 140 out of the opening 120. The handle 140 is pulled upward, thereby lifting the main body 12 with the conversion card 20. Therefore, the conversion card 20 is released from the connector 360. Thus, the mounting apparatus 10 with the conversion card 20 may be easily disengaged from the motherboard 36.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting apparatus for mounting a conversion card to a motherboard of a chassis, the mounting apparatus comprising:
A main body comprising a top board, and a side board extending down from the top board to which the conversion card is fixed; and
an assistant member comprising a handle mounted to the top board adjacent to the conversion card, wherein the handle is arranged to lift the main body together with the conversion card away from the mother board.

2. The mounting apparatus of claim 1, wherein the top board defines an opening adjacent to the side board, the assistant member further comprise two screws and two springs respectively fitted around the screws, opposite ends of the handle are movably fitted about screws respectively, distal ends of the screws are engaged in the top board, to movably mount the handle to the main body and in the opening.

3. The mounting apparatus of claim 2, wherein two nuts are embedded in the top board, each nut comprises a head abutted a top surface of the top board and a pole connected to the head to engage with a corresponding one of the screws.
